(19) United States
(12) Patent Application Publication
(10) Pub. No.: US 2026/0117124 A1
(43) Pub. Date: Apr. 30, 2026

(54) ETCHING LIQUID, ETCHING METHOD, AND METHOD FOR MANUFACTURING SEMICONDUCTOR DEVICE

(71) Applicant: Mitsubishi Chemical Corporation, Tokyo (JP)

(72) Inventors: Hiroyuki SHIRAE, Chiyoda-ku (JP); Tetsuo KASAI; Haru SENDO, Chiyoda-ku (JP)

(73) Assignee: Mitsubishi Chemical Corporation, Tokyo (JP)

(21) Appl. No.: 19/432,682

(22) Filed: Dec. 24, 2025

Related U.S. Application Data
(63) Continuation of application No. PCT/JP2024/023437, filed on Jun. 27, 2024.

(30) Foreign Application Priority Data
Jun. 28, 2023 (JP) 2023-105662
Jun. 28, 2023 (JP) 2023-105665
Jun. 28, 2023 (JP) 2023-105666

(51) Int. Cl. C09K 13/02; H10P 50/64

(52) U.S. Cl. CPC C09K 13/02; H10P 50/642

(57) ABSTRACT

The present disclosure relates to an etching liquid containing an alkaline compound (A) and at least one compound (B) selected from the group consisting of an oxidizing agent (B1) and a cationic surfactant (B2).

### CROSS-REFERENCE TO RELATED APPLICATIONS

This application is a continuation of International Application PCT/JP2024/023437 filed on Jun. 27, 2024, and claims priority to Japanese application No. 2023-105662, 2023-105665 and 2023-105666 filed on Jun. 28, 2023, the disclosures of all of which are incorporated herein by reference in their entireties.

### TECHNICAL FIELD

The present disclosure relates to an etching liquid, an etching method, and a method for manufacturing a semiconductor device.

### BACKGROUND ART

Integrated circuits have been progressively scaled to finer geometries in accordance with Moore's law.

In recent years, studies have been conducted not only to reduce the size of typical planar transistors but also to promote further scaling to finer geometries and higher integration by changing a planar structure to a three-dimensional structure to improve performance as in Fin-type transistors (FinFETs) and gate-all-around transistors (GAAFETs). As a transistor structure that can be expected to achieve further scaling to finer geometries, vertical transistors (VFETs) are being studied. VFETs have even finer geometries and can have improved performance through a structural change from typical planar transistors to vertical structures.

In GAAFETs, nanosheet and/or nanowire-shaped channels are covered with gate electrodes to increase the contact area between the channel and the gate electrode, thereby improving transistor performance per unit area.

VFETs have a structure with nanosheet and/or nanowire-shaped channels stacked in the vertical direction and a smaller standard cell layout area than those of planar transistors (HFETs), thereby improving transistor performance per unit area.

Forming GAAFETs or VFETs requires an etching liquid that dissolves silicon in the etching process. As an etching liquid that dissolves silicon, for example, Patent Literatures 1 and 2 disclose an etching liquid containing an alkaline compound.

### CITATION LIST

### Patent Literature

Patent Literature 1: JP 2017-108122 A
Patent Literature 2: JP 2021-136429 A

### SUMMARY

### Technical Problem

However, the etching liquids disclosed in Patent Literatures 1 and 2 have poor selective dissolution of the (110) plane of silicon crystal relative to the (100) plane of the silicon crystal.

In recent years, scaling to finer geometries has particularly been strongly demanded for FETs, requiring control of orientation-dependent etching of silicon between gaps as narrow as several tens of nanometers. In FETs having a structure formed perpendicular to the (100) plane of a silicon crystal, a nano-shape needs to be formed by etching from the horizontal direction, thus requiring an etching liquid with excellent selective dissolution of the (110) plane of the silicon crystal. In particular, the selective dissolution of each plane orientation is not easy to control because the surface is composed of the same element.

The present disclosure has been made in view of such problems, and an object of the present disclosure is to provide an etching liquid having excellent selective dissolution of the (110) plane of a silicon crystal relative to the (100) plane of the silicon crystal.

Another object of the present disclosure is to provide an etching method, a method for manufacturing a semiconductor device, a method for manufacturing a vertical transistor, and a method for manufacturing a gate-all-around transistor, using the etching liquid.

### Solution to Problem

As a first aspect, the present inventors have found, as a result of diligent studies, that an etching liquid containing an alkaline compound (A) and at least one compound (B) selected from the group consisting of an oxidizing agent (B1) and a cationic surfactant (B2) has excellent selective dissolution of the (110) plane of a silicon crystal relative to the (100) plane of the silicon crystal, thereby completing the present disclosure.

In addition, as a second aspect, the present inventors have found that an etching liquid containing an alkylammonium hydroxide (A1) having an alkyl group with 10 or more carbons has excellent selective dissolution of the (110) plane of a silicon crystal relative to the (100) plane of the silicon crystal, thereby completing the present disclosure.

That is, the gist of the present disclosure is as follows.
[1] An etching liquid containing:
an alkaline compound (A); and
at least one compound (B) selected from the group consisting of an oxidizing agent (B1) and a cationic surfactant (B2),
in which ER₁₁₀/ER₁₀₀>1,
where ER₁₁₀ is an etching rate of a (110) plane of a silicon crystal, and ER₁₀₀ is an etching rate of a (100) plane of the silicon crystal.
[2] The etching liquid according to [1], in which the alkaline compound (A) contains at least one compound selected from the group consisting of a quaternary ammonium hydroxide compound, potassium hydroxide, and calcium hydroxide.
[3] The etching liquid according to [1] or [2], in which the oxidizing agent (B1) contains hydrogen peroxide.
[4] The etching liquid according to any of [1] to [3], in which the cationic surfactant (B2) contains a quaternary ammonium compound.
[5] The etching liquid according to any of [1] to [4], in which the cationic surfactant (B2) contains at least one compound selected from the group consisting of an alkyl group-containing quaternary ammonium compound, a pyridinium ring-containing quaternary ammonium compound, a pyrrolidinium ring-containing quaternary ammonium compound, and a piperidinium ring-containing quaternary ammonium compound.
[6] The etching liquid according to any of [1] to [5], further containing water.
[7] The etching liquid according to [6], in which a content of water in 100 mass % of the etching liquid is 60 mass % or more.
[8] The etching liquid according to any of [1] to [7], in which a content of the alkaline compound (A) in 100 mass % of the etching liquid is from 0.1 mass % to 39.99 mass %.
[9] The etching liquid according to any of [1] to [8], in which a content of the compound (B) in 100 mass % of the etching liquid is from 0.01 mass % to 5 mass %.
[10] The etching liquid according to any of [1] to [9], in which a mass of the compound (B) relative to a mass of the alkaline compound (A) is from 0.001 to 2.
[11] The etching liquid according to any of [1] to [10], in which ER₁₁₁/ER₁₀₀≥0.3, where ER₁₁₁ is an etching rate of a (111) plane of the silicon crystal.
[12] The etching liquid according to any of [1] to [11] for use as an etching liquid for silicon dissolution.
[13] The etching liquid according to any of [1] to [12], in which the etching liquid dissolves the (110) plane of the silicon crystal relative to the (100) plane of the silicon crystal.
[14] The etching liquid according to any of [1] to [13], in which the silicon is single crystal silicon.
[15] An etching method for etching a structure containing silicon using the etching liquid described in any of [1] to [14].
[16] A method for manufacturing a semiconductor device, the method including etching a structure containing silicon using the etching liquid described in any of [1] to [14].
[17] A method for manufacturing a vertical transistor, the method including etching a structure containing silicon using the etching liquid described in any of [1] to [14].
[18] A method for manufacturing a gate-all-around transistor, the method including etching a structure containing silicon using the etching liquid described in any of [1] to [14].
[19] A method for etching a structure containing silicon, the method including selectively etching a (110) plane of a silicon crystal relative to a (100) plane of the silicon crystal using an etching liquid containing an alkaline compound (A) and at least one compound (B) selected from the group consisting of an oxidizing agent (B1) and a cationic surfactant (B2).
[20] A method for manufacturing a semiconductor device, the method including selectively etching a (110) plane of a silicon crystal relative to a (100) plane of the silicon crystal using an etching liquid containing an alkaline compound (A) and at least one compound (B) selected from the group consisting of an oxidizing agent (B1) and a cationic surfactant (B2).

The etching liquid of the present disclosure has excellent selective dissolution of the (110) plane of a silicon crystal relative to the (100) plane of the silicon crystal.

The etching method of the present disclosure, the method for manufacturing a semiconductor device of the present disclosure, the method for manufacturing a vertical transistor of the present disclosure, and the method for manufacturing a gate-all-around transistor of the present disclosure have excellent selective dissolution of the (110) plane of a silicon crystal relative to the (100) plane of the silicon crystal in the etching process, thereby enabling high-precision etching and high-yield manufacture of a desired product.

### DESCRIPTION OF EMBODIMENTS

Hereinafter, the present disclosure will be described in detail, but the present disclosure is not limited to the following embodiments and can be implemented with various modifications within the scope of the gist of the present disclosure. In the present specification, a numerical range expressed using “to” means that the numerical values or physical property values before and after “to” are included in the numerical range.

As a first aspect, an etching liquid of the present disclosure contains an alkaline compound (A) and at least one compound (B) (which may hereinafter be referred to as “the component (B)”) selected from the group consisting of an oxidizing agent (B1) and a cationic surfactant (B2), thereby having excellent selective dissolution of the (110) plane of a silicon crystal relative to the (100) plane of the silicon crystal. The etching liquid of the present disclosure preferably further contains water (which may hereinafter be referred to as “the component (C)”).

The reason for the excellent selective dissolution of the (110) plane of a silicon crystal by the etching liquid of the present disclosure relative to the (100) plane of the silicon crystal is considered as follows.

When a silicon crystal is etched using the etching liquid of the present disclosure, the component (A) dissolves silicon, and the component (B1) partially oxidizes the silicon to silicon oxide. The dissolution rate of silicon by the component (A) depends on the surface proportion of the partially oxidized silicon oxide; the dissolution rate decreases as the surface proportion of the silicon oxide increases. On the other hand, the partial oxidation of the silicon by the component (B1) is more pronounced on the (100) plane of the silicon crystal than on the (110) plane of the silicon crystal. It is considered that, as a result, the etching liquid of the present disclosure has excellent selective dissolution of the (110) plane of a silicon crystal relative to the (100) plane of the silicon crystal.

In addition, the component (B2) adsorbs and protects Si—OH on the surface of the silicon crystal by an ionic bond, thereby suppressing the dissolution of silicon. The adsorption protection for the surface of the silicon crystal by the component (B2) is more pronounced on the (100) plane than on the (110) plane. The acceleration of silicon dissolution by the component (B2) is more pronounced on the (110) plane than on the (100) plane. It is considered that, as a result, the etching liquid of the present disclosure has excellent selective dissolution of the (110) plane of a silicon crystal relative to the (100) plane of the silicon crystal.

As a second aspect, an etching liquid of the present disclosure contains, as the component (A), an alkylammonium hydroxide (A1) (which may hereinafter be referred to as “the component (A1)”) having an alkyl group with 10 or more carbons, thereby having excellent selective dissolution of the (110) plane of a silicon crystal relative to the (100) plane of the silicon crystal. The etching liquid of the present disclosure preferably further contains water (which may hereinafter be referred to as “the component (C)”).

The reason for the excellent selective dissolution of the (110) plane of a silicon crystal by the etching liquid of the present disclosure relative to the (100) plane of the silicon crystal is considered as follows.

When a silicon crystal is etched using the etching liquid of the present disclosure, the component (A1) dissolves silicon as well as adsorbs and protects the surface of the silicon crystal. The adsorption protection for the surface of the silicon crystal by the component (A1) is more pronounced on the (100) plane than on the (110) plane. It is considered that, as a result, the etching liquid of the present disclosure has excellent selective dissolution of the (110) plane of a silicon crystal relative to the (100) plane of the silicon crystal.

Hereinafter, the first aspect will be described.

### First Aspect

### Component (A)

The component (A) is an alkaline compound (A). The etching liquid of the present disclosure contains the alkaline compound (A), thereby having excellent dissolution of silicon.

Examples of the component (A) include organic alkali compounds, such as quaternary ammonium hydroxide compounds (e.g., tetramethylammonium hydroxide, tetraethylammonium hydroxide, and tetrabutylammonium hydroxide); and inorganic alkali compounds, such as metal hydroxides (e.g., sodium hydroxide, potassium hydroxide, and calcium hydroxide). One of these components (A) may be used alone, or two or more may be used in combination. Among these components (A), because of the low content of sodium, which is likely to affect transistor performance, the component (A) is preferably a quaternary ammonium hydroxide compound, potassium hydroxide, or calcium hydroxide, preferably a quaternary ammonium hydroxide compound, and preferably tetramethylammonium hydroxide or tetrabutylammonium hydroxide.

In the perspective of the excellent dissolution of silicon, the content of the component (A) in 100 mass % of the etching liquid is preferably 0.1 mass % or more, preferably 0.2 mass % or more, and preferably 0.5 mass % or more.

In the perspective of the excellent solubility in water, the content of the component (A) in 100 mass % of the etching liquid is preferably 39.99 mass % or less, preferably 34.95 mass % or less, and preferably 29.92 mass % or less.

### Compound (B)

The compound (B) is at least one selected from the group consisting of an oxidizing agent (B1) and a cationic surfactant (B2). The etching liquid of the present disclosure contains an oxidizing agent (B1), thereby promoting the partial oxidation of silicon.

In addition, the etching liquid of the present disclosure contains a cationic surfactant (B2) of the present disclosure, thereby having excellent selective adsorption onto the (100) plane of a silicon crystal and excellent selective dissolution of the (110) plane.

### Oxidizing Agent (B1)

Examples of the oxidizing agent (B1) include hydrogen peroxide, peroxodisulfuric acid or its salts, chlorous acid or its salts, bromic acid or its salts, chromic acid or its salts, perchloric acid or its salts, and nitric acid or its salts. One of these components (B1) may be used alone, or two or more may be used in combination. Among these oxidizing agents (B1), because fewer dangerous reaction products are produced, the oxidizing agent (B1) is preferably hydrogen peroxide, peroxodisulfuric acid or its salt, or chromic acid or its salt, preferably hydrogen peroxide or peroxodisulfuric acid or its salt, and preferably hydrogen peroxide.

In the perspective of promoting the partial oxidation of silicon, the content of the oxidizing agent (B1) in 100 mass % of the etching liquid is preferably 0.01 mass % or more, more preferably 0.05 mass % or more, and even more preferably 0.08 mass % or more.

In the perspective of suppressing the complete oxidation of silicon, the content of the oxidizing agent (B1) in 100 mass % of the etching liquid is preferably 5 mass % or less, preferably 3 mass % or less, and preferably 2 mass % or less.

### Cationic Surfactant (B2)

In the perspective of the excellent solubility in water, the cationic surfactant (B2) is preferably a quaternary ammonium compound, preferably an alkyl group-containing quaternary ammonium compound, a pyridinium ring-containing quaternary ammonium compound, a pyrrolidinium ring-containing quaternary ammonium compound, or a piperidinium ring-containing quaternary ammonium compound, and preferably an alkyl group-containing quaternary ammonium compound.

The cationic surfactant (B2) does not contain the alkaline compound (A).

Examples of the cationic surfactant (B2) include hexadecyltrimethylammonium bromide, octadecyltrimethylammonium bromide, didecyldimethylammonium bromide, dioctadecyldimethylammonium bromide, tetrabutylammonium bromide, tetradecylammonium bromide, benzyldimethylstearylammonium chloride, hexadecylpyridinium chloride, and 1-methyl-1-octylpyrrolidinium chloride. One of these components (B2) may be used alone, or two or more may be used in combination. Among these components (B2), in the perspective of the excellent solubility in water, the cationic surfactant (B2) is preferably hexadecyltrimethylammonium bromide, octadecyltrimethylammonium bromide, or didecyldimethylammonium bromide, preferably hexadecyltrimethylammonium bromide or octadecyltrimethylammonium bromide, and preferably hexadecyltrimethylammonium bromide.

In the perspective of the excellent selective adsorption onto the (100) plane of a silicon crystal and the excellent selective dissolution of the (110) plane, the content of the cationic surfactant (B2) in 100 mass % of the etching liquid is preferably 0.01 mass % or more, more preferably 0.05 mass % or more, and even more preferably 0.08 mass % or more.

In the perspective of the excellent solubility in water, the content of the component (B2) in 100 mass % of the etching liquid is preferably 5 mass % or less, preferably 3 mass % or less, preferably 2 mass % or less, and preferably 1 mass % or less.

### Component (C)

The etching liquid of the present disclosure preferably contains water (component (C)) in addition to the component (A) and the component (B).

In the perspective of the ease of manufacturing the etching liquid and the excellent solubility of the component (A) and the component (B), the content of the component (C) in 100 mass % of the etching liquid is preferably 60 mass % or more, preferably 65 mass % or more, and preferably 70 mass % or more.

In the perspective of the excellent dissolution of silicon, the content of the component (C) in 100 mass % of the etching liquid is preferably 99.5 mass % or less, more preferably 98 mass % or less, and even more preferably 95 mass % or less.

### Additional Component

The etching liquid of the present disclosure may contain an additional component in addition to the component (A), the component (B), and the component (C) as long as the effects of the present disclosure are not impaired; however, the etching liquid may contain no additional component besides the component (A), the component (B), and the component (C).

For example, the content of the additional component in 100 mass % of the etching liquid may be 0.001 mass % or less. In another case, the etching liquid may contain substantially no additional component. The description “the etching liquid may contain substantially no additional component” means that the content of the additional component in 100 mass % of the etching liquid is from 0 mass % to 0.00001 mass %.

Examples of the additional component that may be contained include a chelating agent, a water-miscible solvent, a thiol compound, a nonionic surfactant, a cationic surfactant, and an anionic surfactant.

The etching liquid of the present disclosure contains a chelating agent, thereby exhibiting a chelating effect for silicon crystal plane-specific adsorption.

Examples of the chelating agent include amine compounds, amino acids, and organic acids. One of these chelating agents may be used alone, or two or more may be used in combination. Among these chelating agents, because of the excellent chelating effect, the chelating agent is preferably an amine compound, an amino acid, or an organic acid, and preferably an amine compound.

Examples of the amine compound include ethylenediamine, 1,3-diaminopropane, 1,4-diaminobutane, ethylenediaminetetraacetic acid, diethylenetriaminepentaacetic acid, triethylenetetraminehexaacetic acid, diethylenetriaminepentakis(methylphosphonic acid), ethylenediamine-N,N′-bis[2-(2-hydroxyphenyl)acetic acid], N,N′-bis(3-aminopropyl)ethylenediamine, N-methyl-1,3-diaminopropane, 2-aminoethanol, N-methyldiethanolamine, and 2-amino-2-methyl-1-propanol. One of these amine compounds may be used alone, or two or more may be used in combination. Among these amine compounds, in the perspective of the excellent chelating effect, the amine compound is preferably ethylenediamine, 1,3-diaminopropane, 1,4-diaminobutane, ethylenediaminetetraacetic acid, diethylenetriaminepentaacetic acid, triethylenetetraminehexaacetic acid, diethylenetriaminepentakis(methylphosphonic acid), ethylenediamine-N,N′-bis[2-(2-hydroxyphenyl)acetic acid], N,N′-bis(3-aminopropyl)ethylenediamine, N-methyl-1,3-diaminopropane, 2-aminoethanol, N-methyldiethanolamine, or 2-amino-2-methyl-1-propanol, and preferably ethylenediamine, 1,3-diaminopropane, 1,4-diaminobutane, ethylenediaminetetraacetic acid, diethylenetriaminepentaacetic acid, triethylenetetraminehexaacetic acid, diethylenetriaminepentakis(methylphosphonic acid), or ethylenediamine-N,N′-bis[2-(2-hydroxyphenyl)acetic acid].

Examples of the amino acid include glycine, arginine, histidine, and (2-dihydroxyethyl)glycine. One of these amino acids may be used alone, or two or more may be used in combination. Among these amino acids, in the perspective of the excellent chelating effect, the amino acid is preferably glycine, arginine, histidine, or (2-dihydroxyethyl)glycine, and preferably (2-dihydroxyethyl)glycine.

Examples of the organic acid include oxalic acid, citric acid, tartaric acid, malic acid, and 2-phosphonobutane-1,2,4-tricarboxylic acid. One of these organic acids may be used alone, or two or more may be used in combination. Among these organic acids, in the perspective of the excellent chelating effect, the organic acid is preferably oxalic acid, citric acid, tartaric acid, malic acid, or 2-phosphonobutane-1,2,4-tricarboxylic acid, and preferably citric acid or 2-phosphonobutane-1,2,4-tricarboxylic acid.

In the etching liquid of the present disclosure containing a chelating agent, in the perspective of the excellent chelating effect, the content of the chelating agent in 100 mass % of the etching liquid is preferably 0.001 mass % or more, preferably 0.005 mass % or more, and preferably 0.01 mass % or more.

In the etching liquid of the present disclosure containing a chelating agent, in the perspective of the excellent solubility in water, the content of the chelating agent in 100 mass % of the etching liquid is preferably 25 mass % or less, preferably 10 mass % or less, and preferably 6 mass % or less.

The etching liquid of the present disclosure contains a water-miscible solvent, thereby exhibiting the effect of allowing a hydrophobic substance, which is not miscible with water, to be mixed with water.

The water-miscible solvent is any solvent with excellent solubility in water; preferably a solvent with a solubility parameter (SP value) of 7.0 (cal/cm³)^{1/2} or more and preferably a solvent with a solubility parameter (SP value) of 9.0 (cal/cm³)^{1/2} or more.

Examples of the water-miscible solvent include polar protic solvents, such as isopropanol, ethylene glycol, propylene glycol, methanol, ethanol, propanol, butanol, glycerol, and 2-(2-aminoethoxy)ethanol; polar aprotic solvents, such as acetone, dimethyl sulfoxide, N,N-dimethylformamide, N-methylpyrrolidone, and acetonitrile; and non-polar solvents, such as hexane, benzene, toluene, and diethyl ether. One of these water-miscible solvents may be used alone, or two or more may be used in combination.

In the etching liquid of the present disclosure containing a water-miscible solvent, the content of the water-miscible solvent in 100 mass % of the etching liquid is preferably 5 mass % or less and preferably 1 mass % or less; however, the etching liquid preferably contains no water-miscible solvent.

### Mass Ratio of Each Component

In the perspective of the excellent balance between the dissolution of silicon and the partial oxidation properties of silicon in the case of the oxidizing agent (B1), and the excellent balance between the dissolution of silicon and the selective adsorption onto the (100) plane of the silicon crystal in the case of the cationic surfactant (B2), the mass ratio of the component (B) to the component (A) (mass of component (B)/mass of component (A), hereinafter described as “(B)/(A)”) in the etching liquid of the present disclosure is preferably 2 or less, preferably 1 or less, and preferably 0.5 or less. From similar viewpoints, the ratio is preferably 0.003 or more, preferably 0.005 or more, and preferably 0.01 or more. In addition, the ratio is preferably from 0.003 to 2, preferably from 0.005 to 1, and preferably from 0.01 to 0.5.

In the etching liquid of the present disclosure containing the component (C), in the perspective of the excellent dissolution of silicon, the mass ratio of the component (A) to the component (C) (mass of component (A)/mass of component (C), hereinafter described as “(A)/(C)”) is preferably from 0.001 to 0.7, preferably from 0.003 to 0.6, and preferably from 0.005 to 0.5.

In the etching liquid of the present disclosure containing the component (C), in the perspective of the excellent partial oxidation properties of silicon in the case of the oxidizing agent (B1), and the excellent selective adsorption onto the (100) plane of the silicon crystal and the excellent selective dissolution of the (110) plane of the silicon crystal in the case of the cationic surfactant (B2), the mass ratio of the component (B) to the component (C) (mass of component (B)/mass of component (C), hereinafter described as “(B)/(C)”) is preferably from 0.0001 to 0.08, preferably from 0.0005 to 0.03, and preferably from 0.001 to 0.01. Next, the second aspect of the present disclosure will be described.

### Second Aspect

### Component (A1)

The component (A1) is an alkylammonium hydroxide (A1) having an alkyl group with 10 or more carbons. The etching liquid of the present disclosure contains an alkylammonium hydroxide (A1) having an alkyl group with 10 or more carbons, thereby having excellent selective adsorption onto the (100) plane of the silicon crystal.

In the perspective of the excellent adsorption stability on the silicon crystal surface, the component (A1) is preferably an alkylammonium hydroxide having an alkyl group with 12 to 20 carbons and preferably an alkylammonium hydroxide having an alkyl group with 14 to 18 carbons.

Examples of the component (A1) include hexadecyltrimethylammonium hydroxide, octadecyltrimethylammonium hydroxide, didodecyldimethylammonium hydroxide, and tetradecylammonium hydroxide. One of these components (A1) may be used alone, or two or more may be used in combination. Among these components (A1), in the perspective of the excellent solubility in water, the component (A1) is preferably hexadecyltrimethylammonium hydroxide, octadecyltrimethylammonium hydroxide, or didecyldimethylammonium hydroxide, preferably hexadecyltrimethylammonium hydroxide or octadecyltrimethylammonium hydroxide, and preferably hexadecyltrimethylammonium hydroxide.

In the perspective of the excellent dissolution of silicon, the content of the component (A1) in 100 mass % of the etching liquid is preferably 0.1 mass % or more, preferably 0.2 mass % or more, and preferably 0.5 mass % or more.

In the perspective of the excellent solubility in water, the content of the component (A1) in 100 mass % of the etching liquid is preferably 40 mass % or less, preferably 35 mass % or less, and preferably 30 mass % or less.

### Component (C)

The etching liquid of the present disclosure preferably contains water (component (C)) in addition to the component (A1).

In the perspective of the ease of manufacturing the etching liquid and the excellent solubility of the component (A1), the content of the component (C) in 100 mass % of the etching liquid is preferably 60 mass % or more, preferably 65 mass % or more, and preferably 70 mass % or more.

In the perspective of the excellent dissolution of silicon, the content of the component (C) in 100 mass % of the etching liquid is preferably 99.9 mass % or less, preferably 99.8 mass % or less, and preferably 99.5 mass % or less.

### Additional Component

The etching liquid of the present disclosure may contain an additional component in addition to the component (A1) and the component (C) as long as the effects of the present disclosure are not impaired; however, the etching liquid may contain no additional component besides the component (A1) and the component (C).

For example, the content of the additional component in 100 mass % of the etching liquid may be 0.001 mass % or less. In another case, the etching liquid may contain substantially no additional component. The description “the etching liquid may contain substantially no additional component” means that the content of the additional component in 100 mass % of the etching liquid is from 0 mass % to 0.00001 mass %.

Examples of the additional component that may be contained include a chelating agent, a water-miscible solvent, an oxidizing agent, a thiol compound, a nonionic surfactant, a cationic surfactant, and an anionic surfactant.

The etching liquid of the present disclosure contains a chelating agent, thereby exhibiting a chelating effect for silicon crystal plane-specific adsorption.

Examples of the chelating agent include amine compounds, amino acids, and organic acids. One of these chelating agents may be used alone, or two or more may be used in combination. Among these chelating agents, because of the excellent chelating effect, the chelating agent is preferably an amine compound, an amino acid, or an organic acid, and preferably an amine compound.

Examples of the chelating agent include the same as those described in the first aspect.

In the etching liquid of the present disclosure containing a chelating agent, in the perspective of the excellent chelating effect, the content of the chelating agent in 100 mass % of the etching liquid is preferably 0.001 mass % or more, preferably 0.005 mass % or more, and preferably 0.01 mass % or more.

In the etching liquid of the present disclosure containing a chelating agent, in the perspective of the excellent solubility in water, the content of the chelating agent in 100 mass % of the etching liquid is preferably 25 mass % or less, preferably 10 mass % or less, and preferably 6 mass % or less.

The etching liquid of the present disclosure contains a water-miscible solvent, thereby exhibiting the effect of allowing a hydrophobic substance, which is not miscible with water, to be mixed with water.

Examples of the water-miscible solvent include the same as those described in the first aspect; the water-miscible solvent is used in the same form of use and content as those described in the first aspect.

### Mass Ratio of Each Component

In the etching liquid of the present disclosure containing the component (C), in the perspective of the excellent dissolution of silicon, the mass ratio of the component (A1) to the component (C) (mass of component (A1)/mass of component (C), hereinafter described as “(A1)/(C)”) is preferably from 0.001 to 0.7, preferably from 0.003 to 0.6, and preferably from 0.005 to 0.5.

### Method for Manufacturing Etching Liquid

The method for manufacturing the etching liquid of the first aspect of the present disclosure is not particularly limited; the etching liquid can be manufactured by mixing the component (A) and the component (B), and, if necessary, the component (C) and the additional component.

The method for manufacturing the etching liquid of the second aspect of the present disclosure is not particularly limited; the etching liquid can be manufactured by mixing the component (A1) and, if necessary, the component (C) and the additional component.

The order of mixing is not particularly limited; all the components may be mixed at once, or some components may be mixed in advance and then the remaining components may be mixed.

### Physical Properties of Etching Liquid

In the perspective of the excellent dissolution of silicon, the pH of the etching liquid of the present disclosure is preferably from 8 to 14, preferably from 9 to 14, and preferably from 10 to 14.

When the etching liquid containing the oxidizing agent (B1) as the compound (B) is used in the first aspect, in the perspective of the excellent efficiency of the nano-shape formation in the horizontal direction, the etching rate ER₁₁₀ of the (110) plane of a silicon crystal is preferably 1 nm/min or more, preferably 1.5 nm/min or more, and preferably 2 nm/min or more.

When the etching liquid containing the cationic surfactant (B2) as the compound (B) is used in the first aspect, in the perspective of the excellent efficiency of the nano-shape formation in the horizontal direction, the etching rate ER₁₁₀ of the (110) plane of a silicon crystal is preferably 10 nm/min or more, preferably 20 nm/min or more, and preferably 30 nm/min or more.

In the perspective of the excellent efficiency of the nano-shape formation in the horizontal direction in the second aspect, the etching rate ER₁₁₀ of the (110) plane of a silicon crystal is preferably 10 nm/min or more, preferably 50 nm/min or more, and preferably 100 nm/min or more.

When the etching liquid containing the oxidizing agent (B1) as the compound (B) is used in the first aspect, in the perspective of the excellent efficiency of the nano-shape formation in the horizontal direction, the etching rate ER₁₀₀ of the (100) plane of a silicon crystal is preferably 50 nm/min or less, preferably 30 nm/min or less, and preferably 10 nm/min or less.

When the etching liquid containing the cationic surfactant (B2) as the compound (B) is used in the first aspect, in the perspective of the excellent efficiency of the nano-shape formation in the horizontal direction, the etching rate ER₁₀₀ of the (100) plane of a silicon crystal is preferably 200 nm/min or less, preferably 100 nm/min or less, and preferably 50 nm/min or less.

In the perspective of the excellent efficiency of the nano-shape formation in the horizontal direction in the second aspect, the etching rate ER₁₀₀ of the (100) plane of a silicon crystal is preferably 300 nm/min or less, preferably 200 nm/min or less, and preferably 100 nm/min or less.

When the etching liquid containing the oxidizing agent (B1) as the compound (B) is used in the first aspect, in the perspective of excelling in flat facet formation on the (110) plane of a silicon crystal, the etching rate ER₁₁₁ of the (111) plane of a silicon crystal is preferably 0.5 nm/min or more, preferably 1.0 nm/min or more, and preferably 1.5 nm/min or more.

In the perspective of the excellent dissolution processability in the horizontal direction of a silicon crystal in the first aspect and the second aspect, the selective dissolution (ER₁₁₀/ER₁₀₀) of the (110) plane of the silicon crystal relative to the (100) plane of the silicon crystal is more than 1, preferably from 1.1 to 10, preferably from 1.2 to 7, and preferably from 1.3 to 5.

When the etching liquid containing the oxidizing agent (B1) as the compound (B) is used in the first aspect, in the perspective of the excellent flatness of the (110) plane of the silicon crystal, the selective dissolution (ER₁₁₁/ER₁₁₀) of the (111) plane of the silicon crystal relative to the (110) plane of the silicon crystal is preferably 0.3 or more, preferably from 0.4 to 5, and preferably from 0.5 to 3.

In the present specification, the etching rate and the selective dissolution are measured by the methods described in the Examples below.

### Etching Target of Etching Liquid

The etching liquid of the present disclosure has excellent selective dissolution of the (110) plane of a silicon crystal relative to the (100) plane of the silicon crystal; thus, the etching liquid is suitable as an etching liquid for silicon dissolution and particularly suitable as an etching liquid for dissolving the (110) plane of a silicon crystal relative to the (100) plane of the silicon crystal.

The silicon to be etched is preferably single crystal silicon because it has a crystal plane orientation. The single crystal silicon can be produced by a known method, and may be produced by cutting a single crystal ingot or by epitaxial growth.

### Etching Method

The etching method of the present disclosure is a method for etching a structure containing silicon using the etching liquid of the present disclosure.

The silicon in the structure containing silicon is preferably single crystal silicon because it has a crystal plane orientation. The single crystal silicon can be produced by a known method, and may be produced by cutting a single crystal ingot or by epitaxial growth.

The structure containing silicon may contain a substance besides silicon. Examples of the substance besides silicon include silicon germanium, silicon oxide, silicon nitride, and silicon carbonitride.

As the etching method, a known method can be used; examples include a batch process and a single-wafer process.

In the perspective that the etching rate can be improved, the temperature during etching is preferably 15° C. or higher and preferably 20° C. or higher.

In the perspective of the suppression of damage to a substrate and the provision of etching stability, the temperature during etching is preferably 100° C. or lower and preferably 80° C. or lower.

The temperature during etching corresponds to the temperature of the etching liquid during etching.

### Applications

The etching liquid of the present disclosure has excellent selective dissolution of the (110) plane of a silicon crystal relative to the (100) plane of the silicon crystal; thus, the etching liquid is suitable as an etching liquid for silicon dissolution and particularly suitable as an etching liquid for dissolving the (110) plane of a silicon crystal relative to the (100) plane of the silicon crystal.

Thus, the etching liquid of the present disclosure is suitable for etching a semiconductor device having a structure containing silicon, more suitable for a vertical transistor having a structure containing silicon and a gate-all-around transistor having a structure containing silicon, and particularly suitable for a vertical transistor having a structure containing silicon.

### EXAMPLES

Hereinafter, the present disclosure will be described in more detail using examples; however, the present disclosure is not limited to the description of the following examples without departing from the gist of the present disclosure.

### Selective Dissolution of (110) Plane of Silicon Crystal Relative to (100) Plane of Silicon Crystal

A silicon substrate of a silicon crystal with plane orientations of (110) plane and (100) plane was immersed in a 0.5 mass % aqueous hydrofluoric acid solution for 3 minutes and then rinsed with ultrapure water. Thereafter, the back surface of the silicon substrate was masked, and then the silicon substrate was immersed in an etching liquid obtained in each of examples and comparative examples at 60° C. for 10 minutes to 60 minutes. The film thickness of the silicon substrate before and after immersion was measured with a spectral interference-type film thickness meter, and the selective dissolution of the (110) plane of the silicon crystal relative to the (100) plane of the silicon crystal was calculated using equations (1) to (3) below:

$${ER}_{110} [ nm / min ] = ( film thickness [ nm ] of silicon substrate before immersion - film thickness [ nm ] of silicon substrate after immersion ) / ( immersion time [ min ] ) \qquad ( 1 )$$

$${ER}_{100} [ nm / min ] = ( film thickness [ nm ] of silicon substrate before immersion - film thickness [ nm ] of silicon substrate after immersion ) / ( immersion time [ min ] ) \qquad ( 2 )$$

$$Selective dissolution = {ER}_{110} [ nm / min ] / {ER}_{100} [ nm / min ] \qquad ( 3 )$$

### Selective Dissolution of (111) Plane of Silicon Crystal Relative to (110) Plane of Silicon Crystal

A silicon substrate of a silicon crystal with plane orientations of (111) plane and (110) plane was immersed in a 0.5 mass % aqueous hydrofluoric acid solution for 3 minutes and then rinsed with ultrapure water. Thereafter, the back surface of the silicon substrate was masked, and then the silicon substrate was immersed in an etching liquid obtained in each of examples and comparative examples at 60° C. for 10 minutes to 60 minutes. The film thickness of the silicon substrate before and after immersion was measured with a spectral interference-type film thickness meter, and the selective dissolution of the (111) plane of the silicon crystal relative to the (110) plane of the silicon crystal was calculated using equations (4) to (6) below:

$${ER}_{111} [ nm / min ] = ( film thickness [ nm ] of silicon substrate before immersion - film thickness [ nm ] of silicon substrate after immersion ) / ( immersion time [ min ] ) \qquad ( 4 )$$

$${ER}_{110} [ nm / min ] = ( film thickness [ nm ] of silicon substrate before immersion - film thickness [ nm ] of silicon substrate after immersion ) / ( immersion time [ min ] ) \qquad ( 5 )$$

$$Selective dissolution = {ER}_{111} [ nm / min ] / {ER}_{110} [ nm / min ] \qquad ( 6 )$$

### Raw Materials

The following materials were used as raw materials for manufacturing etching liquids in the examples and comparative examples.
Component (A-1): potassium hydroxide
Component (A-2): tetramethylammonium hydroxide
Component (A-3): tetrabutylammonium hydroxide
Component (B1-1): hydrogen peroxide

### Example 1-1

Components were mixed so that 0.56 mass % of the component (A-1) and 0.10 mass % of the component (B1-1) were contained in 100 mass % of an etching liquid with the remainder being water; the mixture was bubbled with nitrogen gas for 5 minutes, thereby obtaining an etching liquid.

Evaluation results of the obtained etching liquid are shown in Table 1.

### Examples 1-2 to 1-4

Etching liquids were obtained in the same manner as in Example 1-1 except for changing the types and contents of the components in the etching liquids as shown in Table 1.

Evaluation results of the obtained etching liquids are shown in Table 1.

### Comparative Examples 1-1 and 1-2

Etching liquids were obtained in the same manner as in Example 1-1 except for changing the types and contents of the components in the etching liquids as shown in Table 1.

Evaluation results of the obtained etching liquids are shown in Table 1.

TABLE 1

| | | | | | | | | Selective | |
|---|---|---|---|---|---|---|---|---|---|
| | Component (A) | | Component (B1) | | | | | dissolution | |
| | | Content | | Content | Etching rate | | | ER₁₁₀/ | ER₁₁₁/ |
| | Type | [mass %] | Type | [mass %] | ER₁₁₀ | ER₁₀₀ | ER₁₁₁ | ER₁₀₀ | ER₁₁₀ |
| Example 1-1 | (A-1) | 0.56 | (B1-1) | 0.10 | 18.9 | 9.9 | 5.6 | 1.91 | 0.30 |
| Example 1-2 | (A-1) | 0.56 | (B1-1) | 0.20 | 2.2 | 1.4 | 1.9 | 1.64 | 0.86 |
| Example 1-3 | (A-2) | 0.91 | (B1-1) | 0.20 | 1.7 | 1.4 | 0.6 | 1.17 | 0.35 |
| Example 1-4 | (A-3) | 2.59 | (B1-1) | 0.05 | 3.8 | 2.6 | 3.3 | 1.47 | 0.87 |
| Comparative | (A-1) | 0.56 | — | — | 34.2 | 131.2 | 7.3 | 0.26 | 0.21 |
| Example 1-1 | | | | | | | | | |
| Comparative | (A-2) | 0.91 | — | — | 89.0 | 243.6 | 11.9 | 0.37 | 0.13 |
| Example 1-2 | | | | | | | | | |

As can be seen from Table 1, the etching liquids obtained in the examples had significantly excellent selective dissolution of the (110) plane of the silicon crystal relative to the (100) plane of the silicon crystal and also had improved selective dissolution of the (111) plane of the silicon crystal relative to the (110) plane of the silicon crystal.

On the other hand, the etching liquids obtained in the comparative examples had poor selective dissolution of the (110) plane of the silicon crystal relative to the (100) plane of the silicon crystal and poor selective dissolution of the (111) plane of the silicon crystal relative to the (110) plane of the silicon crystal.

### Raw Materials

The following materials were used as raw materials for manufacturing etching liquids in the examples and comparative examples.
Component (A-1): potassium hydroxide
Component (A-2): tetramethylammonium hydroxide
Component (A-3): tetrabutylammonium hydroxide
Component (B2-1): hexadecyltrimethylammonium bromide
Component (B2-2): octadecyltrimethylammonium bromide
Component (B2-3): didecyldimethylammonium bromide
Component (B2-4): dioctadecyldimethylammonium bromide

### Example 2-1

Components were mixed so that 0.56 mass % of the component (A-1) and 1.0 mass % of the component (B2-1) were contained in 100 mass % of an etching liquid, with the remainder being water; the mixture was bubbled with nitrogen gas for 5 minutes, and an etching liquid was obtained.

Evaluation results of the obtained etching liquid are shown in Table 2.

### Examples 2-2 to 2-8

Etching liquids were obtained in the same manner as in Example 2-1 except for changing the types and contents of the components in the etching liquids as shown in Table 2.

Evaluation results of the obtained etching liquids are shown in Table 2.

### Comparative Example 2-1

An etching liquid was obtained in the same manner as in Example 2-1 except for changing the types and contents of the components in the etching liquid as shown in Table 2.

Evaluation results of the obtained etching liquid are shown in Table 2.

TABLE 2

| | Component (A) | | Component (B1) | | | | Selective |
|---|---|---|---|---|---|---|---|
| | | Content | | Content | Etching rate | | dissolution |
| | Type | [mass %] | Type | [mass %] | ER₁₁₀ | ER₁₀₀ | ER₁₁₀/ER₁₀₀ |
| Example 2-1 | (A-1) | 0.56 | (B2-1) | 1.0 | 142.4 | 30.6 | 4.65 |
| Example 2-2 | (A-1) | 0.56 | (B2-1) | 0.1 | 104.5 | 49.7 | 2.10 |
| Example 2-3 | (A-1) | 0.56 | (B2-2) | 0.1 | 80.3 | 41.0 | 1.96 |
| Example 2-4 | (A-1) | 0.56 | (B2-3) | 0.1 | 47.2 | 22.5 | 2.10 |
| Example 2-5 | (A-1) | 0.56 | (B2-4) | 0.1 | 19.4 | 17.2 | 1.13 |
| Example 2-6 | (A-3) | 2.59 | (B2-1) | 0.1 | 152.1 | 47.2 | 3.22 |
| Example 2-7 | (A-2) | 0.91 | (B2-1) | 0.1 | 78.4 | 46.0 | 1.70 |
| Example 2-8 | (A-2) | 0.91 | (B2-1) | 1.0 | 104.0 | 49.2 | 2.11 |
| Comparative | (A-1) | 0.56 | — | — | 34.2 | 131.2 | 0.26 |
| Example 2-1 | | | | | | | |

As can be seen from Table 2, the etching liquids obtained in the examples had significantly excellent selective dissolution of the (110) plane of the silicon crystal relative to the (100) plane of the silicon crystal.

On the other hand, the etching liquid obtained in the comparative example had poor selective dissolution of the (110) plane of the silicon crystal relative to the (100) plane of the silicon crystal.

### Raw Materials

The following materials were used as raw materials for manufacturing etching liquids in the examples and comparative examples.
Component (A1-1): hexadecyltrimethylammonium hydroxide
Component (A′-1): potassium hydroxide
Component (A′-2): tetramethylammonium hydroxide

### Example 3-1

The component (A1-1) was mixed with water so that 3.02 mass % of the component (A1-1) was contained in 100 mass % of an etching liquid, with the remainder being water; the mixture was bubbled with nitrogen gas for 5 minutes, and an etching liquid was obtained.

Evaluation results of the obtained etching liquid are shown in Table 3.

### Comparative Examples 3-1 to 3-2

Etching liquids were obtained in the same manner as in Example 3-1 except for changing the type and content of the component in the etching liquid as shown in Table 3.

Evaluation results of the obtained etching liquid are shown in Table 3.

TABLE 3

| | Component (A) | | | | Selective |
|---|---|---|---|---|---|
| | | Content | Etching rate | | dissolution |
| | Type | [mass %] | ER₁₁₀ | ER₁₀₀ | ER₁₁₀/ER₁₀₀ |
| Example 3-1 | (A1-1) | 3.02 | 123.0 | 56.1 | 2.19 |
| Comparative | (A′-1) | 0.56 | 131.2 | 394.2 | 0.67 |
| Example 3-1 | | | | | |
| Comparative | (A′-2) | 0.91 | 89.0 | 243.6 | 0.37 |
| Example 3-2 | | | | | |

As can be seen from Table 3, the etching liquid obtained in the example had significantly excellent selective dissolution of the (110) plane of the silicon crystal relative to the (100) plane of the silicon crystal.

On the other hand, the etching liquids obtained in the comparative examples had poor selective dissolution of the (110) plane of the silicon crystal relative to the (100) plane of the silicon crystal.

### INDUSTRIAL APPLICABILITY

The etching liquid of the present disclosure has excellent selective dissolution of the (110) plane of a silicon crystal relative to the (100) plane of the silicon crystal; thus, the etching liquid is suitable as an etching liquid for silicon dissolution and particularly suitable as an etching liquid for dissolving the (110) plane of a silicon crystal relative to the (100) plane of the silicon crystal.

Thus, the etching liquid of the present disclosure is suitable for etching a semiconductor device having a structure containing silicon, more suitable for a vertical transistor having a structure containing silicon and a gate-all-around transistor having a structure containing silicon, and particularly suitable for a vertical transistor having a structure containing silicon.

1. An etching liquid comprising:
an alkaline compound (A); and
at least one compound (B) selected from the group consisting of an oxidizing agent (B1) and a cationic surfactant (B2),
wherein ER₁₁₀/ER₁₀₀>1,
where ER₁₁₀ is an etching rate of a (110) plane of a silicon crystal, and ER₁₀₀ is an etching rate of a (100) plane of the silicon crystal.

2. The etching liquid according to claim 1, wherein the alkaline compound (A) comprises at least one compound selected from the group consisting of a quaternary ammonium hydroxide compound, potassium hydroxide, and calcium hydroxide.

3. The etching liquid according to claim 1, wherein the oxidizing agent (B1) comprises hydrogen peroxide.

4. The etching liquid according to claim 1, wherein the cationic surfactant (B2) comprises a quaternary ammonium compound.

5. The etching liquid according to claim 1, wherein the cationic surfactant (B2) comprises at least one compound selected from the group consisting of an alkyl group-containing quaternary ammonium compound, a pyridinium ring-containing quaternary ammonium compound, a pyrrolidinium ring-containing quaternary ammonium compound, and a piperidinium ring-containing quaternary ammonium compound.

6. The etching liquid according to claim 1, further comprising water.

7. The etching liquid according to claim 6, wherein a content of water in 100 mass % of the etching liquid is 60 mass % or more.

8. The etching liquid according to claim 1, wherein a content of the alkaline compound (A) in 100 mass % of the etching liquid is from 0.1 mass % to 39.99 mass %.

9. The etching liquid according to claim 1, wherein a content of the compound (B) in 100 mass % of the etching liquid is from 0.01 mass % to 5 mass %.

10. The etching liquid according to claim 1, wherein a mass of the compound (B) relative to a mass of the alkaline compound (A) is from 0.001 to 2.

11. The etching liquid according to claim 1, wherein ER₁₁₁/ER₁₁₀≥0.3,
where ER₁₁₁ is an etching rate of a (111) plane of the silicon crystal.

12. A silicon dissolution liquid comprising the etching liquid according to claim 1.

13. The etching liquid according to claim 1, wherein the etching liquid dissolves the (110) plane of the silicon crystal relative to the (100) plane of the silicon crystal.

14. The etching liquid according to claim 1, wherein the silicon is single crystal silicon.

15. An etching method for etching a structure containing silicon using the etching liquid according to claim 1.

16. A method for manufacturing a semiconductor device, the method comprising etching a structure containing silicon using the etching liquid according to claim 1.

17. A method for manufacturing a vertical transistor, the method comprising etching a structure containing silicon using the etching liquid according to claim 1.

18. A method for manufacturing a gate-all-around transistor, the method comprising etching a structure containing silicon using the etching liquid according to claim 1.

19. A method for etching a structure containing silicon, the method comprising selectively etching a (110) plane of a silicon crystal relative to a (100) plane of the silicon crystal using the etching liquid according to claim 1.

20. A method for manufacturing a semiconductor device, the method comprising selectively etching a (110) plane of a silicon crystal relative to the (100) plane of the silicon crystal using the etching liquid according to claim 1.
